(19) United States
(12) Patent Application Publication
(10) Pub. No.: US 2026/0107420 A1
(43) Pub. Date: Apr. 16, 2026

(54) LIQUID FILL/DRAIN SYSTEM FOR LIQUID COOLED ELECTRONICS RACKS

(71) Applicant: AMD Design, LLC, Wilmington, DE (US)

(72) Inventors: Sruti CHIGULLAPALLI, Seattle, WA (US); Paul Harold ANDERSON, Leander, TX (US); Divyesh RANA, Clifton, NJ (US); Kevin R. QUALTERS, North Haledon, NJ (US)

(73) Assignee: AMD Design, LLC, Wilmington, DE (US)

(21) Appl. No.: 18/917,308

(22) Filed: Oct. 16, 2024

(51) Int. Cl. H05K 7/20; B65D 88/12; B65D 88/74

(52) U.S. Cl. CPC H05K 7/20781; B65D 88/12; B65D 88/74; H05K 7/20272

(57) ABSTRACT

A method and system for handling an electronics having a liquid coolant system that uses a liquid coolant, the method including: providing the electronics rack with the liquid coolant system in a shipping crate, wherein the liquid coolant system of the rack does not contain the liquid coolant; providing the liquid coolant for the liquid coolant system in a separate storage container; and moving from a first location to a second location the crate with the liquid coolant system of the rack not containing the liquid coolant and the liquid coolant in the separate storage container. The liquid coolant system of the rack preferably is filled at the second location with the liquid coolant from the separate storage container. The system includes the storage container and a pump preferably positioned within the crate and configurable to move the liquid coolant from the storage container into the liquid coolant system.

### FIELD

This disclosure is directed to a method and system to fill and/or drain a liquid coolant system of an electronics rack containing electronic components (e.g., information technology (IT) components) with/of a liquid coolant, particularly useful for transporting such electronics racks.

### BACKGROUND

A plurality of electronic components (e.g. servers, networking equipment, etc.) are often assembled, stacked, and connected together in racks. These pluralities of electronic components often dissipate heat and heat is often detrimental to the performance of the electronic components assembled and contained in the racks. Often these racks contain or integrate a cooling system, for example a liquid coolant system, for cooling the racks and the electronic equipment contained in the racks. The racks having a liquid cooling system for cooling the electronic components are often assembled in a first location and shipped to a second location for installation and operation. The electronic racks with liquid cooling system are often packed in shipping crates for protection of the racks and the electronic components during transit, and the shipping crates are loaded into shipping containers for transport to the second location. The electronic racks with liquid cooling system are often filled with the liquid coolant at the assembly point and shipped in shipping crates to the second location with the liquid coolant already loaded into and contained within the liquid coolant system of the rack.

Shipping the racks of electronic components with a liquid coolant system filled with liquid coolant presents risks of leaks in the liquid coolant system as a result of shocks and vibrations encountered during transport of the racks, and there is an additional risk of liquid coolant leaks and/or pipe bursts due to freezing, for example in non-climate controlled containers (e.g. shipping containers, trucks, etc.). It can be appreciated that leaks of the liquid coolant can present a number of problems for the racks and the electronic components. One potential solution to liquid coolant leaking from liquid coolant systems in racks for electronic components has been to ship the racks without liquid coolant and to fill the coolant system for the rack with liquid coolant at the installation site. However, filling the coolant system at the installation site creates a number of difficulties and problems, including, for example, increasing time at the dock and installation site to fill the liquid coolant system, and the requirement for a tanker containing the liquid coolant to fill many (e.g., dozens, hundreds, thousands,) of racks with liquid coolant. It would be desirable to overcome the problems of shipping the racks with a liquid coolant system filled with liquid coolant and/or filling the racks on-site at the installation and/or operation location.

### SUMMARY

One or more methods, systems, mechanisms, and/or products for handling liquid coolant are described. For example, the methods, systems, mechanisms, and/or products may be used for filling a liquid coolant system with, and/or draining a liquid coolant system of, a liquid. In one or more implementations, the methods, systems, mechanisms, and/or products have applications for filling and/or draining a liquid coolant system of an electronics rack containing a plurality of electronics components.

A system, mechanism, and/or product (referred to as a fill/drain system) as well as methods for handling a liquid coolant for use in a liquid coolant system of an electronics rack for holding a plurality of electronic components (e.g., electronics rack) is disclosed. The fill/drain system in an arrangement has a storage tank subsystem having a storage tank for containing liquid coolant and a pump subsystem having a pump for moving liquid coolant. In an example implementation, the liquid coolant system preferably contains a coolant supply side and a coolant return side, and according to an approach a storage tank outlet of the storage tank is connectable with an inlet of the pump, the coolant supply side is connectable with an outlet of the pump, and the coolant return side is connectable to an inlet of the storage tank inlet. In a further configuration of the fill/drain system, a storage tank outlet connector in flow communication with the storage tank outlet is connectable with a pump inlet connector in flow communication with the pump inlet, a supply side coolant connector in flow communication with the supply side of the liquid coolant is connectable with a pump outlet connector in communication with the pump outlet, and a return side coolant connector in flow communication with the return side of the liquid coolant system is connectable with a storage tank inlet connector in flow communication with the storage tank inlet. In one or more arrangements, the system includes a shipping crate, and the storage container/tank subsystem and pump subsystem are positioned inside of, integrated into, and fixed to the shipping crate.

Further described is one or more example methods of handling, including for example moving and/or transporting, an electronics rack having a liquid coolant system that uses a liquid coolant. An example method includes: providing the electronics rack with the liquid coolant system in a shipping crate, wherein the liquid coolant system of the electronics rack does not contain the liquid coolant; providing the liquid coolant for the liquid coolant system in a separate storage container/tank; and moving, from a first location to a second location, the crate with the electronics rack having a liquid coolant system that does not containing the liquid coolant and liquid coolant located in the separate storage container/tank. The method according to an example implementation further includes providing both the separate storge tank with the liquid coolant and the shipping crate with the rack having a liquid coolant system that does not contain the liquid coolant in the same transit container and moving the crate (with the electronics rack with the liquid coolant system in a dry state) and separate storage container containing the liquid coolant in the same transit container. In a preferred implementation the separate storage container/tank is provided inside the crate with the rack and separate storage container containing the liquid coolant is moved in the crate from the first location to the second location while the separate storage container is located inside the crate with the rack. In a further aspect, the method can include filling at the second location the liquid coolant from the separate storage container/tank into the liquid coolant system of the rack, preferably using a pump, wherein the separate storage container/tank and pump are preferably integrated into, positioned within, and fixedly attached to the shipping crate.

The foregoing summary is illustrative only and is not intended to be in any way limiting. In addition to the illustrative aspects, implementations, and features described above, further aspects, implementations, and features will become apparent by reference to the drawings and the following detailed description. In the drawings, like reference numbers indicate identical or functionally similar elements.

### BRIEF DESCRIPTION OF THE DRAWINGS

FIG. 1 illustrates a back-end view of an example shipping crate for a rack having a plurality of electronics components that includes a liquid cooling system.

FIG. 2 illustrates a front-end view of the example shipping crate of FIG. 1 with a front panel removed to show the rack containing a plurality of electronics components.

FIG. 3 illustrates a side view of the example shipping crate of FIG. 1.

FIG. 4 illustrates a perspective back-end view of an example shipping crate of FIG. 1 with rear end panel removed and the electronics racks configured for transit where the example shipping crate contains an example fill/drain system and/or mechanism for filling and/or draining a liquid coolant system of the electronics rack.

FIG. 5 illustrates a perspective back-end view of an example shipping crate having an example fill/drain system for filling and/or draining a liquid cooling system of an electronics rack with/of a liquid coolant.

FIG. 6 illustrates a block diagram of an example fill/drain system having an example storage subsystem, an example pump subsystem, and an example optional drain tank subsystem for an example electronics rack having a liquid coolant system.

FIG. 7 illustrates an example flow chart of a method for filling and/or draining a liquid coolant of a liquid coolant system of an electronics rack.

FIG. 8 illustrates a box diagram of an example method of performing a pressure test of an example liquid coolant system and/or example fill/drain system.

FIG. 9 illustrates an example of the method of performing a pressure test of a liquid coolant system and/or fill/drain system arranged in an example shipping crate.

FIG. 10 illustrates a box diagram of a method of filling a liquid coolant system of an electronics rack with liquid coolant using the fill/drain system of FIGS. 6-7.

FIG. 11 illustrates an example box diagram of an example method of draining a liquid coolant system of an electronics rack to an optional drain tank.

FIG. 12 illustrates another box diagram of another example method of draining a liquid coolant system of an electronics rack to an optional drain tank.

FIG. 13 illustrates an example of the connections of an example optional drain system to drain the liquid coolant from the liquid coolant system of an electronics rack to an optional drain tank.

FIG. 14 illustrates a box diagram of an example method of moving a liquid coolant from a drain tank to a storage tank using an example liquid fill/drain system.

FIG. 15 illustrates an example of the connections of the example fill/drain system to move liquid coolant from the drain tank of example drain tank subsystem to the storage tank of the storage tank subsystem.

FIG. 16 is a cross-sectional view of an implementation of a drain tank.

FIG. 17 is a cross-sectional view of an implementation of an integrated storage tank and drain tank.

### DETAILED DESCRIPTION

### Overview

Racks containing electronic components (referred herein as “electronics racks” or “racks”), such as, for example, servers, networking gear, etc., are generally assembled in a first location and transported to a second location where the electronics racks are installed and operated. These electronics racks are known to generate heat and often include liquid coolant systems to dissipate the heat and keep the electronics at an operating temperature that does not jeopardize and/or unduly decrease the performance or lifespan of the electronic components of the electronics rack. The liquid coolant systems contain a liquid coolant and shipping the electronics racks filled with liquid coolant can be undesirable as leaks can develop as a result of shock and vibration during transport, and/or pipes, hoses, connectors, and/or other components can fail and leak due to freezing of the liquid coolant. Moreover, shipping the electronics racks without liquid coolant and filling the liquid coolant system of the electronics racks can be problematic as logistics of having a tanker to fill the many (dozens, hundreds, thousands of) electronics racks and the down time spent at the dock of the installation facility creates other problems. It is desirable to overcome these problems of handling, e.g., shipping and installing, electronics racks and provide a more efficient and less problematic manner of transporting, handling, and/or installing electronics racks that are liquid cooled.

Described herein is a system, mechanism, product and/or method for handling a liquid coolant for use in a liquid coolant system of an electronics rack for holding a plurality of electronic components (e.g., electronics rack). The system, mechanism, and/or product, referred to as a fill/drain system, in an arrangement has a storage tank subsystem and a pump subsystem. In an example implementation the storage tank subsystem has a storage tank for containing liquid coolant, a storage tank inlet, and a storage tank outlet. In a preferred implementation, the storage tank inlet is in communication with a storage tank inlet connector and the storage tank outlet is in communication with a storage tank outlet connector. In a further example implementation, the pump subsystem has a pump for pumping liquid coolant, an inlet to the pump, and an outlet to the pump. In a preferred implementation, the pump inlet is in communication with a pump inlet connector and the pump outlet is in communication with a pump outlet connector. In an example implementation, the liquid coolant system preferably contains a coolant supply side and a coolant return side, and in a preferred arrangement the coolant supply side is in communication with a supply side coolant connector and the coolant return side is in communication with a coolant return side connector. The fill/drain system according to an approach is configured and/or adapted so that the storage tank outlet is connectable with the pump inlet, the coolant supply side is connectable with the pump outlet, and the coolant return side is connectable to the storage tank inlet. In a further arrangement of the fill/drain system, the storage tank outlet connector is connectable with the pump inlet connector, the supply side coolant connector is connectable with the pump outlet connector, and the return side coolant connector is connectable with the storage tank inlet connector.

In one or more arrangements, the system includes a shipping crate, and the storage container/tank subsystem and pump subsystem are positioned inside of, integrated into, and fixed to the shipping crate. In one or more implementations, one or more of the storage tank subsystems, the storage tank, the pump subsystem, and/or the pump are associated with and/or attached to the electronics rack. The fill/drain system and/or shipping crate in an arrangement is reuseable for reshipping electronics racks and can optionally include at least one of a foam packing group consisting of: storage tank foam wrapping, pump foam wrapping, hose foam wrapping, and combinations thereof. In an implementation, the storage container/tank subsystem and/or of pump subsystem has a shutoff valve to resist and/or control flow of the liquid coolant.

The fill/drain system can optionally include a drain tank subsystem having an inlet to a drain tank and the coolant return side of the liquid coolant system is connectable to the drain tank subsystem. The drain tank subsystem preferably is located inside of, integrated into, and fixed to a shipping crate. In a further implementation the drain tank and storage tank are integrated into a single housing having a partition to separate a drain tank compartment from a storage tank compartment. In one or more arrangements, at least one of the storage tank or the drain tank has one or more baffles and/or fins configured to decrease movement of the liquid coolant during transport of the shipping crate. The system can further optionally include a pressure gauge, preferably located inside the shipping crate, connected to and/or connectable to the liquid coolant system and/or fill/drain system.

Further described is one or more example methods of handling, including for example moving and/or transporting, an electronics rack having a liquid coolant system that uses a liquid coolant. An example method includes: providing the electronics rack with the liquid coolant system in a shipping crate, wherein the liquid coolant system of the electronics rack does not contain the liquid coolant; providing the liquid coolant for the liquid coolant system in a separate storage container/tank; and moving, from a first location to a second location, the crate with the electronics rack having a liquid coolant system that does not containing the liquid coolant and liquid coolant located in the separate storage container/tank. The method according to an example implementation further includes providing both the separate storge tank with the liquid coolant (either inside or outside the shipping crate) and the shipping crate with the rack having a liquid coolant system that does not contain the liquid coolant in the same transit container and moving the crate and separate storage container with the liquid coolant in the separate storage container/tank in the same transit container. In a preferred implementation the separate storage container/tank is provided inside the crate with the rack and separate storage container containing the liquid coolant is moved in the crate from the first location to the second location while the separate storage container is located inside the crate with the rack. In a further aspect, the method can include filling at the second location the liquid coolant from the separate storage container/tank into the liquid coolant system of the rack. According to another optional example method, the rack is moved from the first location to the second location with inert gas in the coolant system of the rack, where the inert gas is preferably nitrogen.

According to a further optional step, the method includes checking the pressure of the inert gas in the liquid coolant system of the rack before filling the rack with the liquid coolant, and in a further optional step can include purging the inert gas in the liquid coolant system of the rack before filling the rack with the liquid coolant. According to one or more aspects, the method includes providing the crate with a storage container/tank subsystem and a pump subsystem, wherein the storage container/tank subsystem has the storage container/tank, a storage container inlet connector, and a storage container outlet connector and the pump subsystem has a pump inlet connector and a pump outlet connector, and filling the liquid coolant system of the rack includes: connecting the storage outlet connector to the pump inlet connector; connecting the pump outlet connector to a supply side connector of the liquid coolant system of the rack; connecting the storage container inlet connector to a return side connector of the liquid coolant system of the rack; and causing the pump to move the liquid coolant from the storage container to the liquid coolant system.

The method can optionally include draining the liquid coolant from the liquid coolant system of the rack, for example, for reshipping the electronics rack. The liquid coolant can be drained from the liquid coolant system of the electronics rack to the storage container. In an optional arrangement, the crate is provided with a drain container subsystem comprising a drain container having an optional drain tank connector (e.g., drain connector), and draining the liquid coolant from the liquid coolant system of the rack includes: connecting the drain tank, for example the drain tank connector, to a coolant return side, for example using a return side connector, of the liquid coolant system of the rack; connecting a coolant supply side, for example using a supply side connector, of the liquid coolant system of the rack to at least one of a compressed air cylinder or a vent; and filling the drain container with the liquid coolant from the liquid coolant system of the rack. In a further optional aspect, the method can include moving the liquid coolant from the optional drain container to the storage container, where in an optional method, moving the liquid coolant from the drain container to the storage container includes: connecting the drain tank, for example using the drain tank connector, to a pump inlet of a pump; connecting a pump outlet of the pump to a storage container, for example using a storage tank inlet connector in communication with the storage container; and pumping the liquid coolant from the drain tank into the storage container using the pump.

In the following description, numerous specific details are set forth, such as particular structures, components, materials, dimensions, processing steps and techniques, in order to provide an understanding of the various implementations of the present application. However, it will be appreciated by one of ordinary skill in the art that the various implementations of the present application may be practiced without these specific details. In other instances, well-known structures or processing steps have not been described in detail in order to avoid obscuring the present application.

### Example Environment

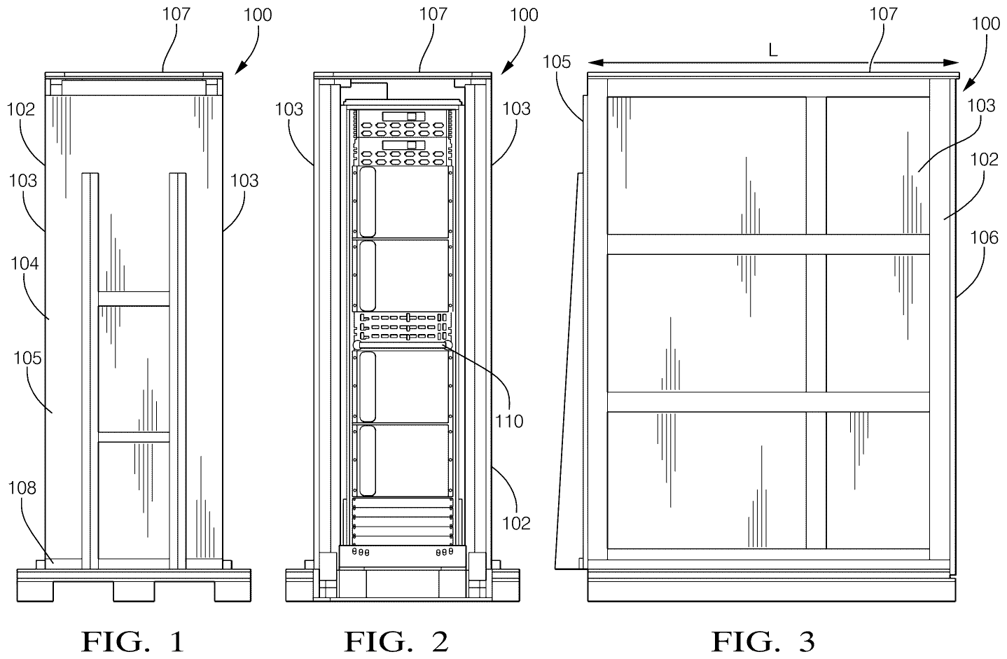

FIGS. 1-4 illustrate an example environment for fill/drain system 100 where the environment includes shipping crate 102 for handling and transporting one or more racks holding electronics components (hereinafter “electronics racks” or “racks”), for example servers, networking components, etc. An example electronics rack can be a graphics processor unit (GPU) field replacement unit (FRU), also referred to as a GPU FRU. Shipping crates are for protecting the electronics racks during transport from a first location where the electronics racks typically are assembled, to a second location, where the electronics racks are typically installed and operated. Shipping crate 102 has side panels 103, end panels 104 including front-end panel 105 and back-end panel 106, top panel 107, and bottom panel 108. Generally, the front-end panel 105 and back-end panel 106 are removeable to load and remove the one or more electronics racks (e.g., electronics rack(s) 110) from shipping crate 102. Shipping crates for electronics racks generally are fixed in height and width but are flexible in depth (e.g., the length L of side panel 103).

### Example Implementation

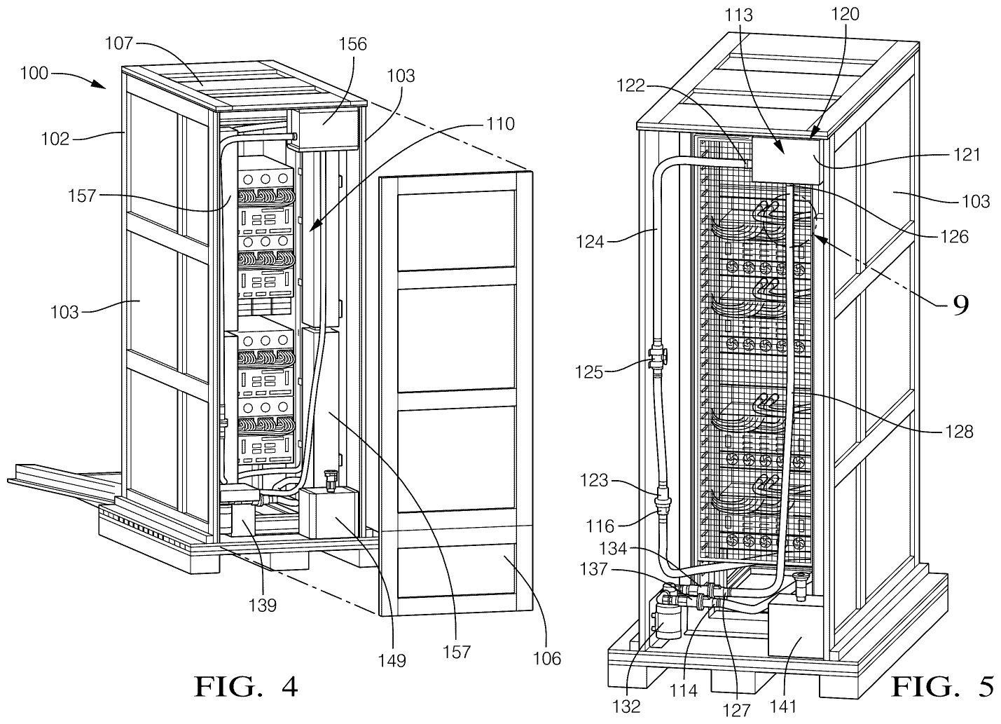

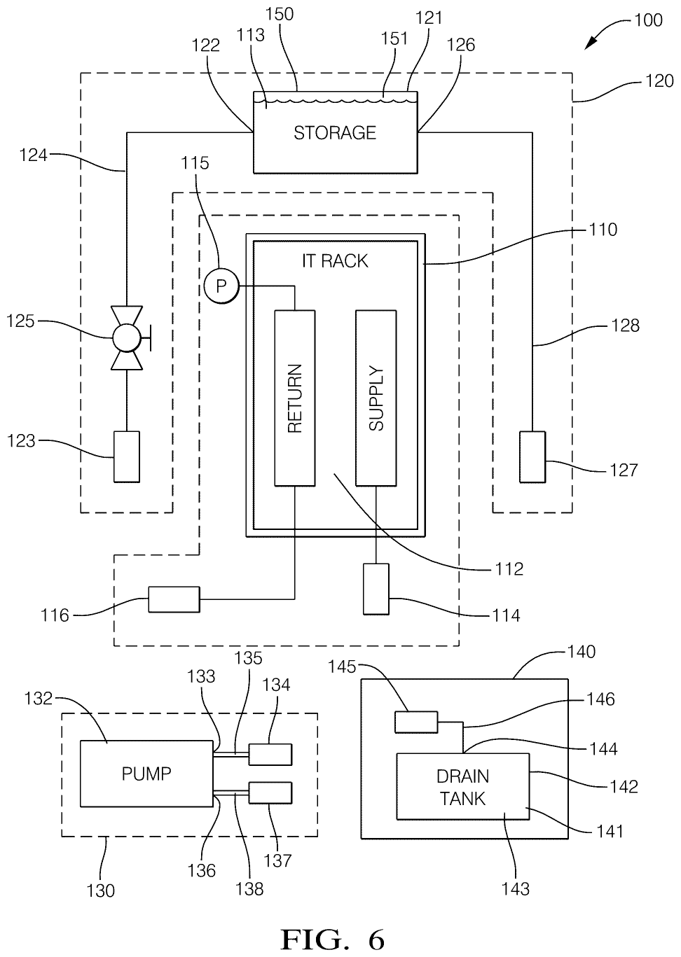

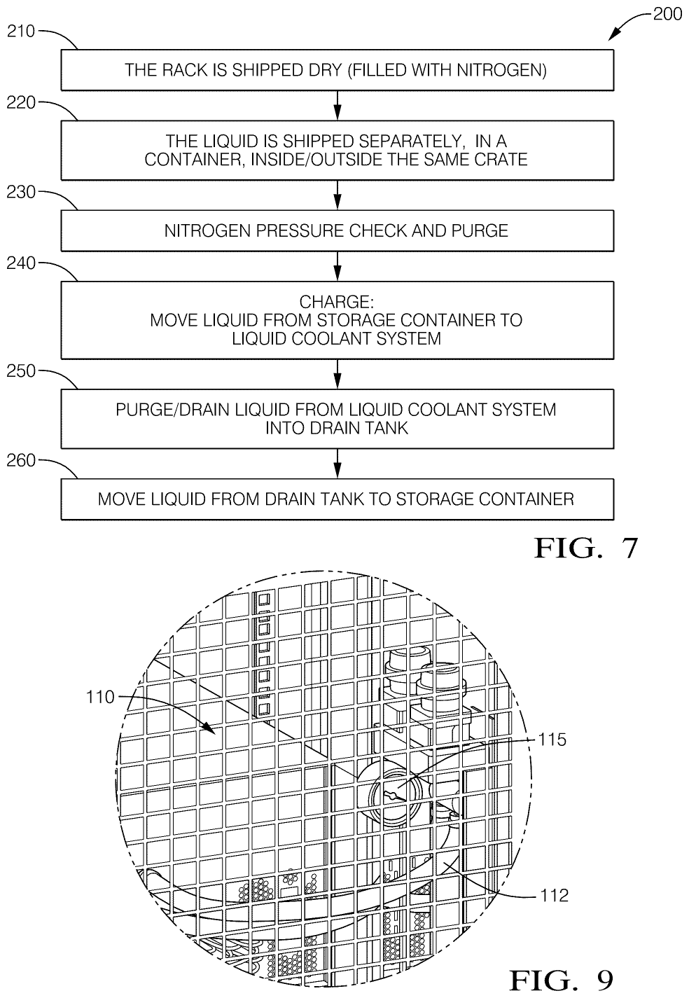

FIGS. 4-6 illustrate an example implementation of a fill/drain system 100 (e.g., a fill, delivery, and/or drain mechanism, referred to herein as “fill system”, “fill/delivery system”, “delivery system”, “drain system”, “fill/drain system”, “delivery/drain system”, and/or “fill/delivery/drain system”, depending upon context) for filling and/or draining a liquid coolant 113 from a liquid coolant system 112 of an electronics rack 110. Liquid coolant system 112 of electronics rack 110 generally includes about 3 to 4 gallons of liquid coolant 113, in an implementation about 3.5 gallons of liquid coolant 113, although other quantities and/or volumes of liquid coolant used in a liquid coolant system of an electronics rack are contemplated. The liquid coolant system 112 and/or electronics rack 110 preferably has a coolant supply side that includes a supply side connector 114 and a coolant return side that preferably includes a return side connector 116. The liquid coolant system 112 can optionally include a pressure gauge 115 for measuring the fluid pressure in liquid coolant system 112. Pressure gauge 115 can optionally be included as part of fill/drain system 100 and can be configured to measure the fluid pressure in liquid coolant system 112 (including in fill/drain system 100).

Example fill/drain system 100 for filling and/or draining liquid coolant system 112 includes storage tank subsystem 120 and pump subsystem 130. Fill/drain system 100 may further include drain tank subsystem 140 for draining the liquid coolant system 112 of the electronics rack 110.

Storage tank subsystem 120 (also referred to as “storage container subsystem” or “storage tank subsystem”) includes a storage tank 121 (also referred to as “storage container” or “storage tank”) for holding liquid coolant 113. Storage tank 121 includes a storage tank housing 150, storage tank inlet 122 and storage tank outlet 126. Storage tank housing 150 of storage tank 121 creates a chamber 151 for holding and containing liquid coolant 113

As shown in FIG. 16, storage tank housing 150 may optionally contain one or more baffles 152 (e.g., fins) to decrease movement (e.g. sloshing) of the liquid coolant 113 during transit of liquid coolant 113 in storage tank 121. Baffles 152, in an implementation, include partition walls 153 that create multiple compartments 154. The partition walls 153 can extend from end to end and side to side of the storage tank housing 150 or may be partial walls that have an end that does not join with the storage tank housing 150, and partition walls 153 may have one or more openings 155.

Storage tank subsystem 120 in an arrangement further includes a storage tank inlet connector 123 in communication with storage tank inlet 122 and optionally can further include a storage tank inlet hose 124 extending between storage tank inlet 122 and storage tank inlet connector 123 for transporting liquid coolant 113 between storage tank inlet 122 and storage tank inlet connector 123. Storage tank subsystem 120 in an arrangement further includes a storage tank outlet connector 127 in communication with storage tank outlet 126 and optionally can further include a storage tank outlet hose 128 extending between storage tank outlet 126 and storage tank outlet connector 127 for transporting liquid coolant 113 between storage tank outlet 126 and storage tank outlet connector 127. Storage tank subsystem 120 can optionally include at least one shut-off valve 125, where shut-off valve 125 can be located between storage tank inlet connector 123 and storage tank inlet 122 (e.g., along storage tank inlet hose 124) and/or can be located between storage tank outlet connector 127 and storage tank outlet 126 (e.g., along storage tank outlet hose 128).

Pump subsystem 130 in one or more example implementations includes pump 132 having a pump inlet 133 and pump outlet 136. Pump inlet connector 134 can be located at or in communication with pump inlet 133 and/or pump inlet hose 135 can extend between pump inlet 133 and pump inlet connector 134. Pump outlet connector 137 can be located at or in communication with pump outlet 136 and/or pump outlet hose 138 can extend between pump outlet 136 and pump outlet connector 137. Fill/drain system 100 including storage tank subsystem 120 and pump subsystem 130 are preferably arranged and configured inside shipping crate 102, preferably integrated into and fixedly attached to shipping crate 102. In one or more implementations, one or more of the storage tank subsystem, the storage tank, the pump subsystem, or the pump are associated with and/or attached to the electronics rack.

As discussed in more detail below, fill/drain system 100 for filling the liquid coolant system 112 of electronics rack 110 including storage tank subsystem 120 and pump subsystem 130 can be configured to fill liquid coolant system 112 of electronics rack 110 with liquid coolant 113 contained in storage tank 121. It can be appreciated that fill/drain system 100 including storage tank subsystem and/or pump subsystem 130 while illustrated as being located within shipping crate 102, preferably integral with and/or fixedly attached to the shipping crate 102 and/or electronics rack, fill/drain system 100 can be located outside and separate from the shipping crate 102, but preferably in the transit container (not shown), for example, shipping container, containing one or more of the shipping crates 102 loaded with electronics racks 110.

Fill/drain system 100 can further include drain tank subsystem 140 shown in FIGS. 4-6 to drain the liquid coolant 113 from the liquid coolant system 112 of the electronics rack 110, for example for of electronic components and/or return of an electronic rack. Drain tank subsystem 140 in an arrangement includes a drain tank 141 (hereinafter also referred to as “drain container” or “drain tank”). Drain tank 141 includes a drain tank housing 142 forming a chamber 143 for holding liquid coolant 113. Drain tank 141 further includes a drain tank inlet/outlet 144 to permit filling and/or emptying drain tank 141. Drain tank inlet/outlet 144 is in communication with drain tank connector 145. Drain tank subsystem 140 can optionally further include a drain tank hose 146 extending between drain tank inlet/outlet 144 and drain tank connector 145 to assist with and/or transport liquid coolant 113 to and from drain tank 141. As explained below, liquid coolant 113 from the liquid coolant system can also be drained into storage tank 121 of storage tank subsystem.

As discussed in more detail below, fill/drain system 100 for filling, draining, and/or refilling the liquid coolant system 112 of electronics rack 110 including storage tank subsystem 120, pump subsystem 130, and drain tank subsystem 140 can be configured to fill liquid coolant system 112 of electronics rack 110 with liquid coolant 113 contained in storage tank 121, to drain liquid coolant 113 from liquid coolant system 112 into drain tank 141, and/or refilling liquid coolant 113 from drain tank 141 into liquid coolant system 112. It can be appreciated that fill/drain system 100 including storage tank subsystem 120, pump subsystem 130, and/or drain tank subsystem 140 while illustrated as being located within shipping crate 102, preferably integral with and/or fixedly attached to the shipping crate 102 and/or electronics rack 110, fill/drain system 100 can be located outside and separate from the shipping crate 102, but preferably in the transit container (not shown), for example, shipping container, containing one or more of the shipping crates 102 loaded with electronics racks 110.

### Example Installation

FIGS. 4-5, 9, 13, and 15 illustrates example installations of fill/drain system 100 in preferred environment of shipping crate 102 where all of fill/drain system 100 is (including all subsystems are) located inside the shipping crate 102 with one or more electronics racks 110. As illustrated, the storage tank subsystem 120 including the storage tank 121 is located inside shipping crate 102 preferably at the top of shipping crate 102 and, in an implementation, storage tank 121 is located in the top right corner of shipping crate 102. Storage tank 121 as illustrated in FIG. 4 is preferably wrapped in storage tank foam wrapping 156 to protect storage tank 121 from damage during shipping. As illustrated, pump subsystem 130 including pump 132 is located inside shipping crate 102 and, in an arrangement, pump 132 is located along the bottom preferably in the bottom left corner of shipping crate 102. Pump 132 as illustrated in FIG. 4 is preferably wrapped in pump foam wrapping 139 to protect pump 132 from damage during shipping. As illustrated, drain tank subsystem 140 including drain tank 141 is located inside shipping crate 102 and, in an arrangement, drain tank 141 is located in the bottom right corner of shipping crate 102. Drain tank 141 as illustrated in FIG. 4 is preferably wrapped in drain tank foam wrapping 149 to protect drain tank 141 from damage during shipping. Chassis foam wrapping 157 can also be included in shipping crate 102 to protect fill/drain system 100 including components of storage tank subsystem 120, pump subsystem 130, and/or drain tank subsystem 140 from damage during shipment and/or further protect electronics rack 110 from damage during shipment.

Moreover, fill/drain system 100, including storage tank subsystem 120, pump subsystem 130, and/or drain tank subsystem 140 (optional) is preferably integral with and fixedly attached to shipping crate 102. Preferably, fill/drain system 100, including storage tank subsystem 120, pump subsystem 130, and/or drain tank subsystem 140 is integrated with and fixedly attached to shipping crate 102 in a manner that permits reuse of fill/drain system 100 and/or shipping crate 102. It can be appreciated that system 100 has been illustrated with storage tank subsystem 120, pump subsystem 130, and/or drain tank subsystem 140 being located within shipping crate 102 in preferred locations, however, it can be appreciated that fill/drain system 100 including each of storage tank subsystem 120, pump subsystem 130, and/or drain tank subsystem 140 can be located in different locations within shipping crate 102. In addition, while fill/drain system 100, including storage tank subsystem 120, pump subsystem 130, and/or drain tank subsystem 140, is illustrated as being located within shipping crate 102, preferably integral with and/or fixedly attached to the shipping crate 102, in one or more implementations, one or more of the storage tank subsystem, the storage tank, the pump subsystem, the pump, the drain tank subsystem, and/or the drain tank are associated with and/or attached to the electronics rack. Alternatively, fill/drain system 100 can be located outside and separate from the shipping crate 102, but preferably in the transit container (not shown), for example, a shipping container, containing one or more of the shipping crates 102 loaded with electronics racks 110. In an example implementation, fill/drain system 100 and/or one or more of subsystems (e.g., storage tank subsystem 120, pump subsystem 130, and/or drain tank subsystem 140) can be located outside of and fixed to shipping crate 102.

Example Use

FIG. 7 illustrates an exemplary flowchart of a method 200 of handling an electronics rack having a liquid coolant system that includes moving and/or shipping one or more electronics rack(s) each having a liquid coolant system that does not contain any liquid coolant in the liquid coolant system from a first location to a second location and thereafter filling the liquid coolant system of the electronics rack with liquid coolant at the second location. While the method 200 is described for the sake of convenience and not with an intent of limiting the disclosure as comprising a series and/or number of steps, it is to be understood that the process and/or method does not need to be performed as a series of steps and/or the steps do not need to be performed in the order shown and described in FIG. 7, but the process may be integrated and/or one or more steps may be performed together, simultaneously, or the steps may be performed in the order disclosed or in an alternative order.

At 210, method 200 in an implementation includes shipping an electronics rack dry. That is, at 210 the electronics rack with liquid coolant system is shipped without liquid coolant in the liquid coolant system from a first location to a second location. In an arrangement the first location can be where the electronics rack is assembled, and the second location can be where the electronics rack is installed and/or used. In one or more implementations, at 210, an electronics rack having a liquid coolant system is provided in a shipping crate without any liquid coolant in the liquid coolant system of the electronics rack. In an arrangement the electronics rack provided in the shipping crate is shipped without any liquid coolant in the liquid coolant system from a first location to a second location. In an arrangement, the liquid coolant system is provided with an inert gas, preferably nitrogen gas. For example, the electronics rack filled with inert gas in its liquid cooling system is provided in a shipping crate, and preferably the one or more electronic(s) racks are shipped from a first location to a second location with inert gas in the one or more liquid coolant system(s) of the one or more electronics rack(s).

At 220, liquid coolant for the liquid coolant system of the electronics rack is shipped separately from the liquid coolant system and/or the electronics rack from a location (e.g., the first location (same location from where the rack is shipped or a third different location) to the second location (location where the electronics rack is shipped). In an implementation, liquid coolant at 220 is shipped in a storage tank or container separate from the electronics rack and/or liquid coolant system preferably to the second location. Preferably at 220 the liquid coolant for the liquid coolant system of the electronics rack is provided separately from the electronics rack and/or system and preferably in a separate storage tank or container and preferably in a separate storage tank or container located in the same shipping crate as the electronics rack, and the liquid coolant preferably is shipped in the separate storage tank or container within the shipping crate containing the electronics rack. The separate storage tank located within the shipping crate with the electronics rack preferably is configured to contain and/or contains enough liquid coolant to fill the liquid coolant system of the one or more electronics rack(s) in the shipping crate, but in an arrangement is not configured to and/or does not contain enough liquid coolant to fill multiple liquid coolant systems of multiple electronics racks. Alternatively, at 220 the liquid coolant can be shipped in a separate storage tank or container outside of the shipping crate (for example adjacent to the shipping crate, attached to the outside of the shipping crate) but preferably in the same transit container (e.g., same truck) as the shipping crate holding the electronics rack. In one or more implementations, the separate storage tank or container can contain enough liquid coolant for a plurality (e.g., two, dozens, hundreds, and/or thousands) of liquid coolant systems of a plurality of electronic racks.

In one or more implementations of method 200, steps 210 and 220 can include providing an electronics rack with a liquid coolant system in a shipping crate wherein the liquid coolant system of the electronics rack does not contain any liquid coolant, providing the liquid coolant for the liquid coolant system of the electronics rack in a separate storage tank or container in the same transit container that contains the shipping crate containing the electronics rack where the separate storage tank can be located inside or outside the shipping crate containing the electronics rack, and moving and/or shipping both the separate storage tank containing the liquid coolant and the crate containing the electronics rack that is not filled with liquid coolant. In one or more implementations the separate storage tank can be part of storage tank subsystem 120, and in a further implementation, the separate storage tank can be part of fill/drain system 100 that includes storage tank subsystem 120, pump subsystem 130, and/or drain tank subsystem 140.

In one or more implementations, method 200 can include: providing an electronics rack (e.g., electronics rack 110) with a liquid coolant system (e.g., liquid coolant system 112) in an arrangement in a shipping crate (e.g., shipping crate 102, without liquid coolant (e.g., liquid coolant 113)), that is with liquid coolant system not filled with liquid coolant, and preferably filled with insert gas, preferably nitrogen gas; providing fill/drain system 100 including a storage tank subsystem (e.g., storage tank subsystem 120), a pump subsystem (e.g., pump subsystem 130), and/or optionally drain tank subsystem (e.g., drain tank subsystem 140 in the same transit container, preferably in the interior of the same shipping crate (e.g., shipping crate 102) as the electronics rack, where the storage tank subsystem, preferably a storage tank (e.g., storage tank 121) separate from the liquid coolant system contains liquid coolant (to be later added to the liquid coolant system as described below); and moving the shipping crate in the transit container with the liquid coolant in the fill/drain system (e.g., fill/drain system 100), preferably the storage tank subsystem (e.g., storage tank subsystem 120) and storage tank (e.g., storage tank 121) with the electronics rack without liquid coolant in the liquid coolant system from a first location to a second location.

At 230, optionally a pressure check is performed on the liquid coolant system of the electronics rack and/or the fill/drain system (e.g., fill/drain system 100) to determine if there has been any damage to the liquid coolant system and/or the fill/drain system, for example as a result of damage during transit. In one or more implementations a pressure gauge is used to perform the pressure check at 230. In one or more implementations a pressure gauge (e.g., pressure gauge 115) is included as part of liquid cooling system (e.g., liquid coolant system 112) of an electronics rack (e.g., electronics rack 110) and/or as part of the fill/drain system. In an example implementation a user checks the pressure gauge to see if the liquid coolant system and/or fill/drain system is under pressure (e.g., about 5 psi). The pressure gauge is preferably checked at the second location after shipment and/or movement of the electronics rack.

In a further arrangement, if pressure is maintained, then at 230 the inert gas, preferably the nitrogen gas, within the liquid coolant system of the electronics rack is purged. In one or more implementations, one or more of the supply side connector (e.g., supply side connector 114) or valve and/or the return side connector (e.g., return side connector 116) or valve is opened to let inert gas dissipate and/or leak from the system. In one or more implementations the gas can be purged through use of a vent, or other means. For example, either of the supply side connector 114 and/or the return side connector 116 can be vented (e.g., connected to a vent). Additionally, and/or alternatively, a valve can be included in the liquid coolant system for purging the liquid coolant system of the inert gas and/or liquid coolant. If the pressure is not maintained, then the liquid coolant system can be repaired and/or the liquid coolant system and/or electronics rack can be shipped to a location for repair.

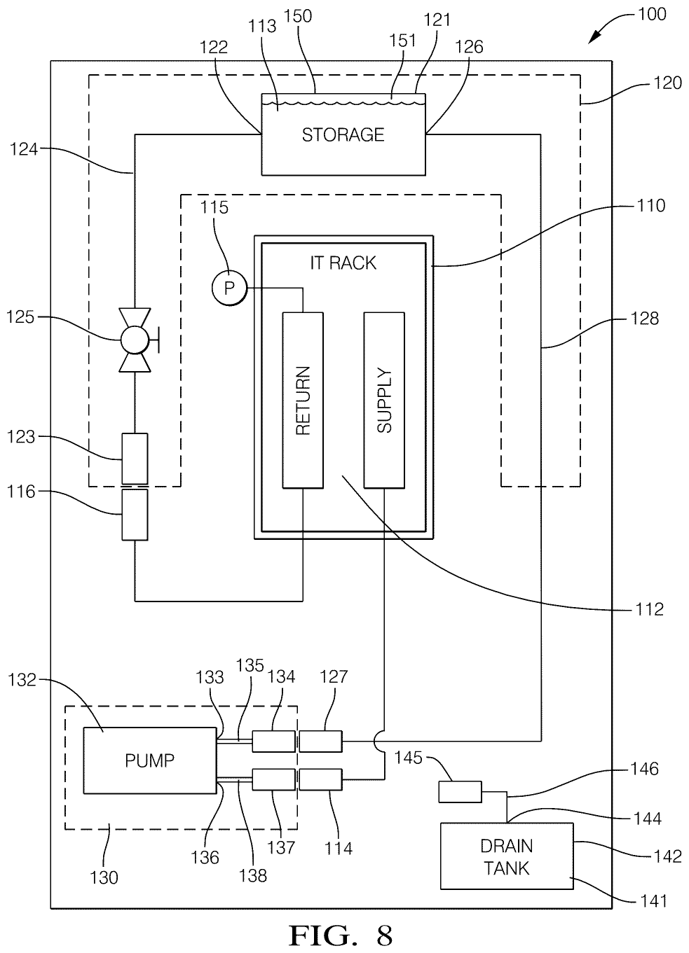

FIGS. 8-9 illustrate an implementation of checking the pressure of the liquid coolant system (e.g., liquid coolant system 112) and/or fill/drain system (e.g., fill/drain system 100) at 230. In an arrangement, at 230, storage tank outlet connector 127 is connected to pump inlet connector 134, pump outlet connector 137 is connected to supply side connector 114 of liquid coolant system 112, return side connector 116 is connected to storage tank inlet connector 123, and pressure gauge 115 is checked. It can be appreciated that storage tank outlet connector 127 is configured to mate and connect to pump inlet connector 134, pump outlet connector 137 is configured to mate and connect to supply side connector 114 of liquid coolant system 112, and return side connector 116 is configured to mate and connect to storage tank inlet connector 123. If the system is functional, the pressure gauge (e.g., pressure gauge 115) should read a pressure that is on or about the pressure at which the liquid coolant system of the electronics rack was pressurized using inert gas, preferably nitrogen gas. If the pressure is maintained, the inert gas within the liquid coolant system can be purged by opening one or more of the supply side connector 114 and/or the return side connector 116, and/or a valve in the liquid coolant system and/or the fill/drain system 100.

Method 200 in an implementation continues at 240 where the liquid coolant system of the electronics rack is filled with liquid coolant, preferably after moving and/or shipping the electronics to a second location, for example a location where the electronics rack is to be installed and/or operated.

In one or more configurations, the separate storage tank filled with liquid coolant used to fill the liquid coolant system is part of a storage tank subsystem (e.g., storage tank subsystem 120) and/or part of a fill/drain system (e.g., fill/drain system 100) which can optionally further include a pump as part of a pump subsystem (e.g., pump subsystem 130) and/or a drain tank as part of a drain tank subsystem (e.g., drain tank subsystem 140). The storage tank subsystem (e.g., storage tank subsystem 120) and/or the fill/drain system (e.g., fill/drain system 100), which can optionally further include a pump as part of a pump subsystem (e.g., pump subsystem 130) and/or a drain tank as part of a drain tank subsystem (e.g., drain tank subsystem 140), can be associated with, attached to, located within, attached inside of, integral with the shipping crate that contains and/or is loaded with the electronics rack.

In one or more implementations, the shipping crate used to ship and/or move the electronics rack is provided with and/or contains a fill/drain system (e.g., fill/drain system 100) having a storage container subsystem (e.g., storage tank subsystem 120) and a pump subsystem (e.g., pump subsystem 130) with or without an optional drain tank subsystem (e.g., drain tank subsystem 140). In one or more configurations, storage tank subsystem 120 preferably includes storage tank 121, storage tank inlet connector 123, and storage tank outlet connector 127 and pump subsystem 130 has a pump 132, pump inlet connector 134, and pump outlet connector 137.

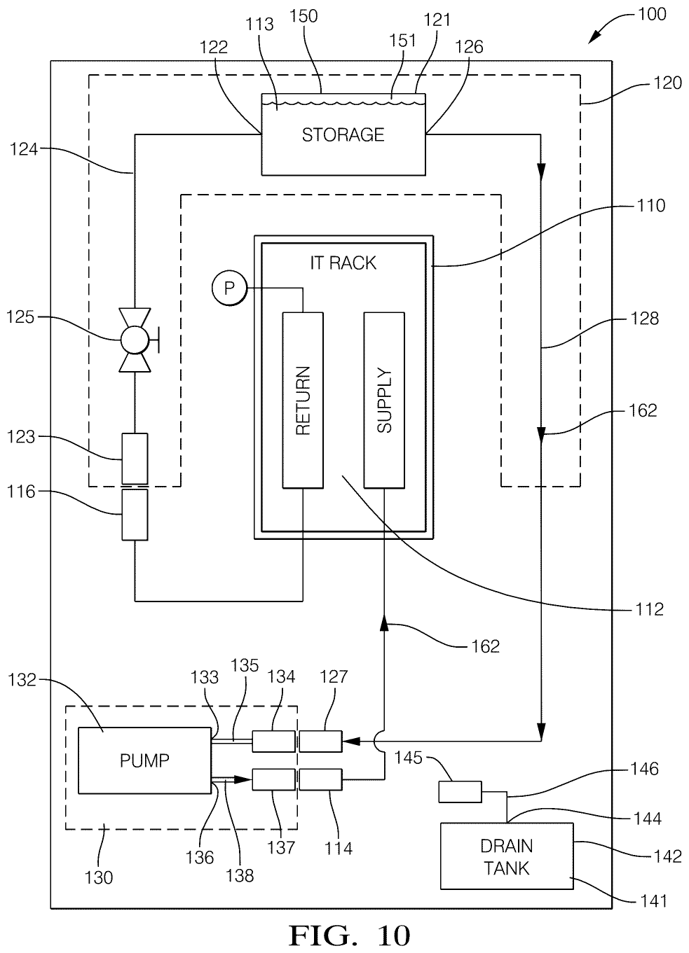

Filling the liquid coolant system of the electronics rack at 240 is illustrated at FIG. 10 where the storage tank outlet connector 127 is connected to the pump inlet connector 134, pump outlet connector 137 is connected to supply side connector 114 of the liquid coolant system 112 of the electronics rack 110, and the storage tank inlet connector 123 is connected to return side connector 116 of liquid coolant system 112 of the electronics rack 110. With the connections in place, the pump 132 of the pump subsystem 130 is run and/or operated to create a flow of liquid coolant 113 as illustrated by arrows 162 in closed circuit 160 to remove the liquid coolant 113 from the storage tank 121 of storage tank subsystem 120 and fill liquid coolant system 112 of the electronics rack 110 with the liquid coolant 113 from the storage tank 121. It can be appreciated that storage tank outlet connector 127 is configured to mate and connect to pump inlet connector 134, pump outlet connector 137 is configured to mate and connect to supply side connector 114 of liquid coolant system 112, and return side connector 116 is configured to mate and connect to storage tank inlet connector 123.

Method 200 in an implementation can optionally include at 250 draining liquid coolant from the liquid coolant system of the electronics rack. Draining the liquid coolant from the liquid coolant system of the electronics rack can be useful if reshipping and/or moving the electronics storage rack, for example in case of returning the electronics rack for repair (e.g., as part of a return merchandise authorization (RMA)). In an implementation, the liquid coolant (e.g., liquid coolant 113) in the liquid coolant system (e.g., liquid coolant system 112) in the electronics rack (e.g., electronics rack 110) can be drained into the storage tank subsystem and/or storage tank (e.g., storage tank 121) using for example pump subsystem and/or a pump (e.g., pump 132).

In one or more configurations, a drain tank/container (e.g., drain tank 141), for example as part of a drain tank subsystem (e.g., drain tank subsystem 140) can be used at 250 to drain liquid coolant from the liquid coolant system of the electronics rack. That is, in an implementation a drain system (e.g., fill/drain system 100 including drain tank subsystem 140) is used at 250 to empty liquid coolant from a liquid coolant system of an electronics rack, where the liquid coolant from the liquid coolant system is emptied into the drain tank (e.g., drain tank 141) in a drain tank subsystem (e.g., drain tank subsystem 140). In one or more arrangements at 250 the liquid coolant system is connected to the drain tank and liquid coolant from the liquid coolant system is drained into the drain tank.

In one or more implementations the drain tank that receives the liquid coolant from the liquid coolant system is part of a drain tank subsystem (e.g., drain tank subsystem 140) and/or part of a drain/fill system (e.g., fill/drain system 100), which can optionally further include a storage tank as part of a storage tank subsystem (e.g., storage tank subsystem 10) and/or a pump as part of a pump subsystem (e.g., pump subsystem 130). The drain tank subsystem (e.g., drain tank subsystem 140) and/or the drain/fill system (e.g., fill/drain system 100), which can further include a storage tank as part of a storage tank subsystem (e.g., storage tank subsystem 120) and/or a pump as part of a pump subsystem (e.g., pump subsystem 130), can be associated with, attached to, located within, attached inside of, and/or integral with the shipping crate that contains and/or is loaded with the electronics rack.

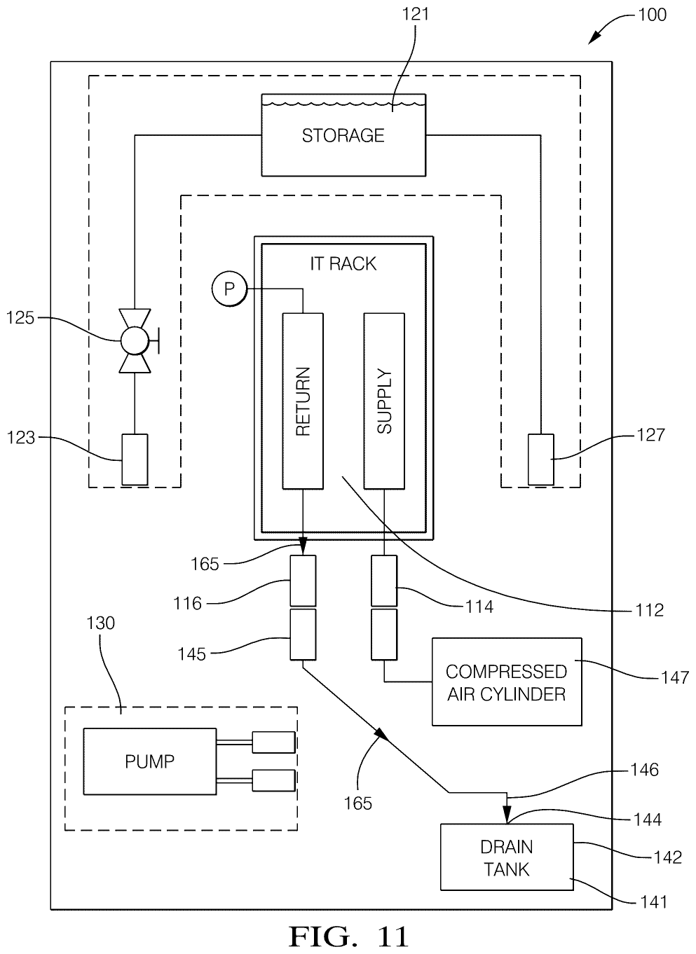

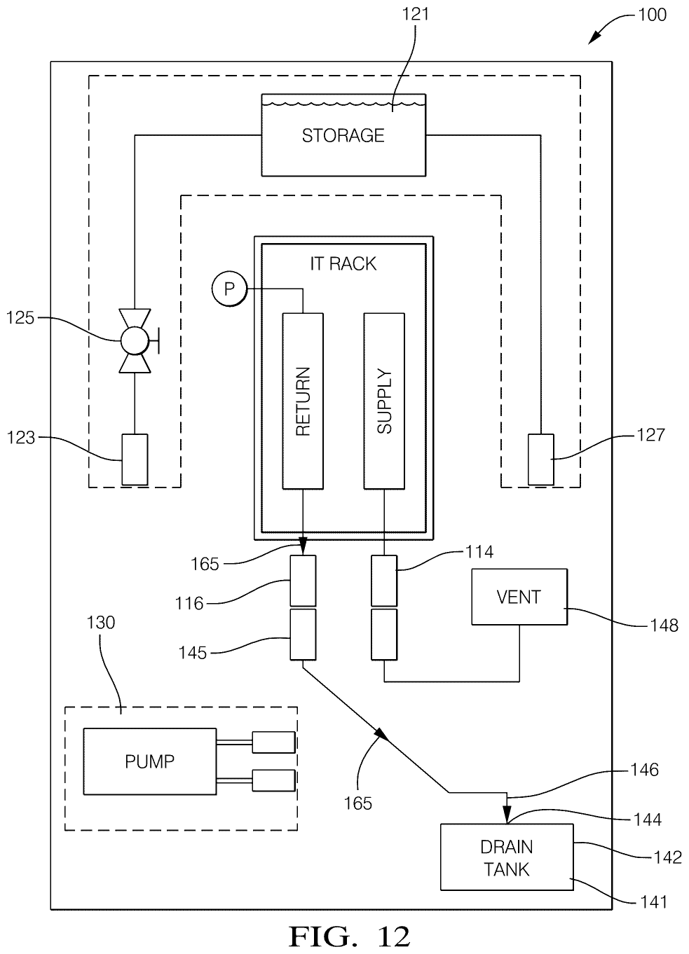

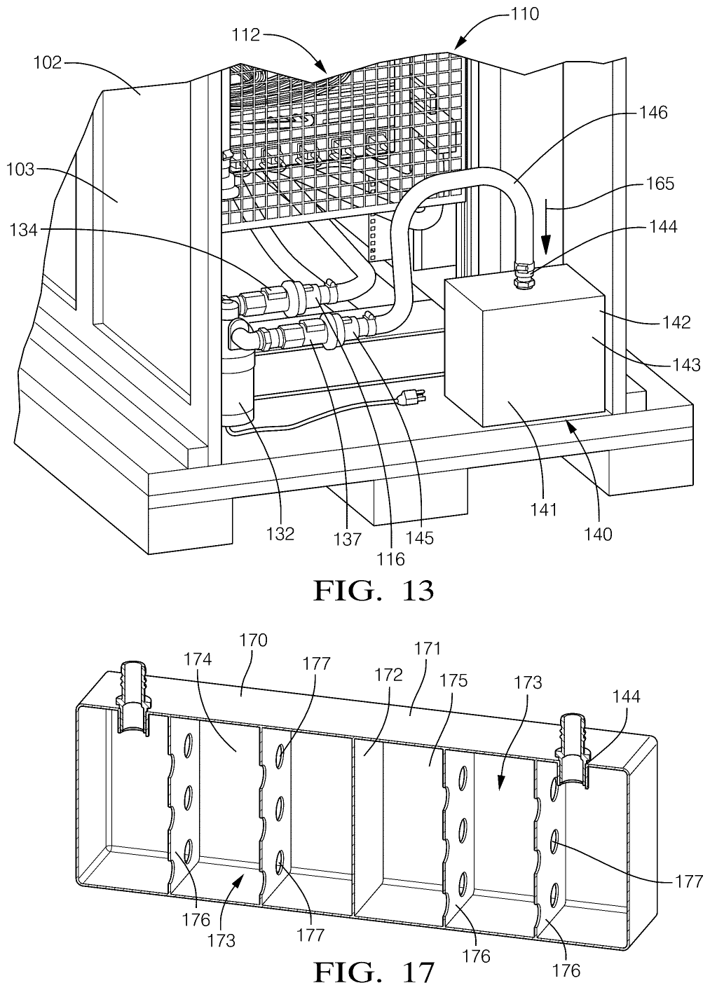

In one or more implementations, the shipping crate used to ship and/or move the electronics rack is provided with and/or contains a drain system (e.g., fill/drain system 100) having a drain tank subsystem (e.g., drain tank subsystem 140). The drain system can further be a fill/drain system that includes a storage tank subsystem (e.g., storage tank subsystem 120) and a pump subsystem (e.g., pump subsystem 130). In one or more configurations the drain tank subsystem (e.g., drain tank subsystem 140) has a drain tank 141 and a drain tank connector 145. Draining the liquid coolant 113 from the liquid coolant system 112 of the electronics rack 110 at 250 in one or more implementations includes using fill/drain system 100 where fill/drain system 100 includes drain tank subsystem 140 (where fill/drain system 100 can also be configured as fill/drain system 100 having storage tank subsystem 120 and pump subsystem 130). Draining the liquid coolant system 112 of the electronics rack 110 at 250 is illustrated at FIGS. 11-13 where the drain tank connector 145 is connected to return side connector 116 and supply side connector 114 is connected to compressed gas 147, e.g., compressed air cylinder, as shown in FIG. 11, or a vent 148 as shown in FIG. 12. The liquid coolant 113 flows as illustrated by arrows 165 from liquid coolant system 112 into drain tank 141. It can be appreciated that drain tank connector 145 is configured to mate and connect to return side connector 116 and supply side connector 114 is configured to connect to the compressed gas 147 (e.g., via a gas cylinder connector) and/or the vent 148 (e.g., via a vent connector). In one or more implementations, as shown in FIG. 13, the return side connector 116 is connected to pump inlet connector 134 and drain tank connector 145 is connected to pump outlet connector 137 and liquid coolant 113 flows as shown by arrows 165 from the liquid coolant system 112 through pump 132 and into drain tank 141.

In one or more implementations, the shipping crate is provided with at least one power source configured to supply operational power to the pump subsystem 130. For example, the power source may be a power cord, a power receptacle, plug, or port, a battery, a capacitor, a generator, a solar panel, or some combination thereof.

In one or more implementations, the shipping crate is provided with at least one elevation structure configured to facilitate movement of the shipping crate. For example, the elevation structure may include slots or spaces disposed near a bottom of the shipping crate that are configured to receive forks of a forklift or a pallet jack. Alternatively or additionally, the elevation structure may include hooks, eyes, or openings disposed near a top of the shipping create that are configured to facilitate lifting of the shipping crate via a crane or hoist.

While method 200 of handling an electronics rack with a liquid coolant system has been described in implementations in connection with the use of fill/drain system 100 it can be appreciated that method 200 of filling the liquid coolant system at 240 and/or draining the liquid coolant system at 250 can be implemented without fill/drain system 100 (with one or more of storage tank subsystem 120, pump subsystem 130, and/or drain tank subsystem 140), and/or with alternative delivery and/or drain systems.

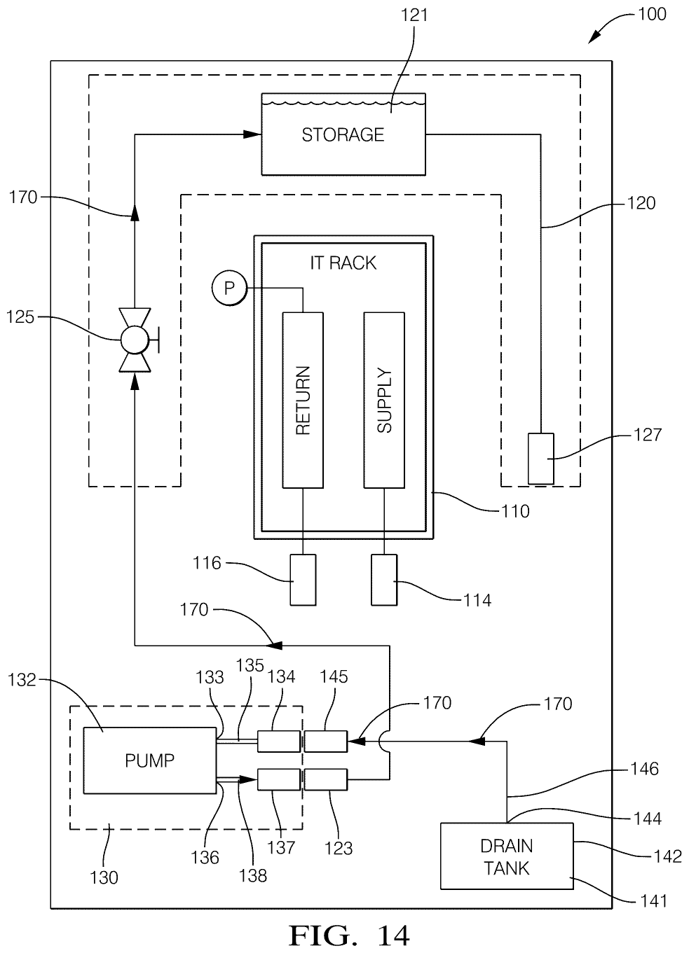

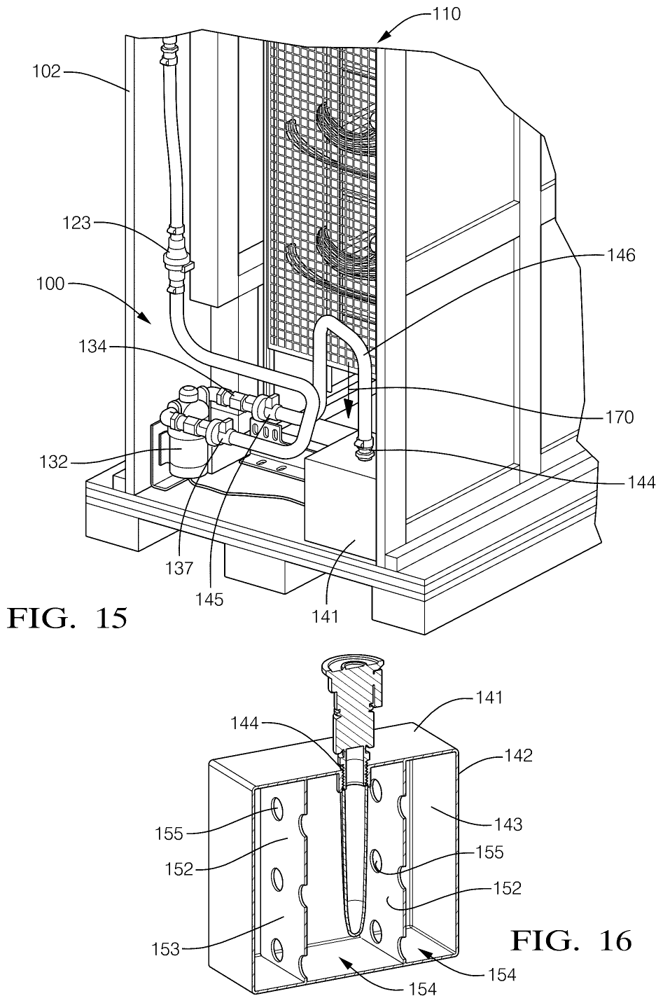

Method 200 can further optionally include at 260 moving liquid coolant from drain tank to a storage tank. In one or more implementations, a pump is used at 260 to move liquid coolant from a drain tank to a storage tank. In one or more implementations fill/drain system 100 is used to move liquid from drain tank 141 in drain tank subsystem 140 to storage tank 121 in storage tank subsystem 120 using pump 132 from pump subsystem 130. An implementation of moving liquid coolant at 260 from the drain tank 141 to storage tank 121 is illustrated in FIGS. 14-15. As shown in FIGS. 14-15 drain tank connector 145 is connected to pump inlet connector 134 of pump inlet 133 and pump outlet connector 137 is connected to storage tank inlet connector 123 and pump 132 is run to move fluid from the drain tank 141 into the storage tank 121. The liquid coolant flows according to arrows 170 in FIGS. 14-15 from drain tank 141 to pump 132 and from pump 132 into storage tank 121.

In an implementation, the liquid coolant system (e.g., liquid coolant system 112) of electronics rack (e.g., electronic rack 110) is filled at 240 with liquid coolant 113 that was shipped and/or moved in a storage tank (e.g., storage tank 121) separate from the electronics rack, and in one or more arrangements the liquid coolant is preferably contained in a separate storage tank located in the same transit container as the electronics rack, more preferably in a separate storage tank associated with (e.g. attached to) the shipping crate that is used to move and/or ship the electronics rack with liquid cooling system, more preferably the separate tank is located inside the shipping crate used to move and/or ship the electronics rack.

In an implementation, the liquid coolant system (e.g., liquid coolant system 112) of electronics rack (e.g., electronic rack 110) is drained of liquid coolant 113 at 250 into a drain tank that was shipped and/or moved in shipping crate separate from the electronics rack, and in one or more arrangements the liquid coolant is preferably drained into a drain tank located in the same transit container as the electronics rack, more preferably in a drain tank associated with (e.g. attached to) the shipping crate that is used to move and/or ship the electronics rack with liquid cooling system, more preferably located inside and fixedly attached to the shipping crate used to move and/or ship the electronics rack.

In an implementation, the liquid coolant is drained at 260 from a drain tank into a storage tank where both the drain tank and the storage tank were shipped and/or moved in shipping crate that contains the electronics rack where the drain tank and storage tank are separate from the liquid coolant system of the electronics rack, and in one or more arrangements the liquid coolant is preferably drained from a drain tank into a storage tank where both the drain tank and the storage tank are located in the same transit container as the electronics rack, more preferably both the drain tank and storage tank are associated with (e.g. attached to) the shipping crate that is used to move and/or ship the electronics rack with liquid cooling system, more preferably both the drain tank and storage tank are located inside and fixedly attached to the shipping crate used to move and/or ship the electronics rack.

In one or more implementations, one or more of the storage tank subsystem, the storage tank, the pump subsystem, the pump, the drain tank subsystem, and/or the drain tank are associated with and/or attached to the electronics rack.

### Further Implementations

In one or more implementations, drain tank 141 includes a drain tank housing 142 that creates a chamber 143 for holding and containing liquid coolant 113 and may optionally contain as shown in FIG. 16 one or more baffles 152 to decrease movement (e.g. sloshing) of the liquid coolant 113 during transit of the liquid coolant 113 in drain tank 141. Baffles 152 in an implementation includes partition walls 153 that create multiple compartments 154. The partition walls 153 can extend from end to end and side to side of the drain tank housing 142 or may be partial walls that have an end that does not join with the drain tank housing 142, and partition walls 153 may have one or more openings 155.

In one or more implementations, storage tank 121 includes a storage tank housing 150, storage tank inlet 122 and storage tank outlet 126. Storage tank housing 150 of storage tank 121 creates a chamber 151 for holding and containing liquid coolant 113 and may optionally contain one or more baffles 152 (See e.g., FIG. 17) to decrease movement (e.g. sloshing) of the liquid coolant 113 during transit of liquid coolant 113 in storage tank 121. Baffles 152 in an implementation includes partition walls 153 that create multiple compartments 154. The partition walls 153 can extend from end to end and side to side of the storage tank housing 150 or may be partial walls that have an end that does not join with the storage tank housing 150, and partition walls 153 may have one or more openings 155.

In one or more configurations, storage tank 121 in storage tank subsystem 120 and drain tank 141 in drain tank subsystem 140 in fill/drain system 100 can be integrated into a multi-compartment tank 178, as illustrated in FIG. 17. Multi-compartment tank 178 has a housing 171 and a partition 172 that partitions and/or divides multi-compartment tank 178 into multiple compartments 173, for example, storage/supply chamber 174 and drain chamber 175.

Storage/supply chamber 174 would hold and contain liquid coolant 113 during transit and operate as described in connection with storage tank 121. Drain chamber 175 would hold and contain liquid coolant 113 that is emptied from liquid coolant system as described in connection with drain tank 141. Multi-compartment tank 178 can optionally include baffles and/or fins 176 having openings 177 in one or more of multiple compartments 173 to decrease movement and sloshing of liquid during movement.

### EXAMPLES

Example 1: A system for handling liquid coolant for use in a liquid coolant system for a rack for holding a plurality of electronic components, wherein the liquid coolant system has a coolant supply side and a coolant return side, the system comprising: a storage tank subsystem having a storage tank for containing liquid coolant, a storage tank inlet, and a storage tank outlet; and a pump subsystem having a pump for pumping liquid coolant, a pump inlet, and a pump outlet, wherein the storage tank outlet is connectable with the pump inlet, the coolant supply side is connectable with the pump outlet, and the coolant return side is connectable to the storage tank inlet.

Example 2: The system according to example 1, further including a shipping crate, wherein the storage tank subsystem and the pump subsystem are at least one of positioned inside of the shipping crate, integrated into the shipping crate, or fixed to the shipping crate.

Example 3: The system according to example 2, wherein the shipping crate is reuseable for reshipping the rack for holding the electronic components.

Example 4: The system according to any preceding example, further including a shut-off valve in the storage tank subsystem or the pump subsystem for resisting flow of the liquid coolant.

Example 5: The system according to any preceding example, wherein: the storage tank subsystem further includes a storage tank inlet connector in communication with the storage tank inlet and a storage tank outlet connector in communication with the storage tank outlet, the pump subsystem further includes a pump inlet connector in communication with the pump inlet and a pump outlet connector in communication with the pump outlet, the liquid coolant system further includes a supply side coolant connector in communication with the coolant supply side and a return side coolant connector in communication with the coolant return side, and the storage tank outlet connector is connectable with the pump inlet connector, the supply side coolant connector is connectable with the pump outlet connector, and the return side coolant connector is connectable with the storage tank inlet connector.

Example 6: The system according to any preceding example, further including a drain tank subsystem having a drain tank inlet in communication with a drain tank, wherein the coolant return side is connectable to the drain tank subsystem.

Example 7: The system according to example 6, wherein the drain tank and storage tank are integrated into a single housing.

Example 8: The system according to example 6 or 7, wherein the storage tank or the drain tank has a baffle configured to decrease movement of the liquid coolant during transport of the system.

Example 9: The system according to any preceding example, further including storage tank foam wrapping, pump foam wrapping, or hose foam wrapping.

Example 10: A method of handling a rack for holding a plurality of electronic components having a liquid coolant system that uses a liquid coolant, the method comprising: providing the rack with the liquid coolant system in a shipping crate, wherein the liquid coolant system of the rack does not contain the liquid coolant; providing the liquid coolant for the liquid coolant system in a separate storage container; and moving from a first location to a second location the shipping crate with the liquid coolant system of the rack not containing the liquid coolant and the liquid coolant in the separate storage container.

Example 11: The method of example 10 further including: providing both the separate storage container containing the liquid coolant and the rack with the liquid coolant system not containing the liquid coolant in a same transit container; and moving the same transit container having both the separate storage container with the liquid coolant and the shipping crate with the rack.

Example 12: The method of example 10 or 11, further including providing the separate storage container inside the shipping crate with the rack and moving the liquid coolant in the separate storage container from the first location to the second location while the separate storage container is inside the shipping crate with the rack.

Example 13: The method of any of examples 10-12, wherein the rack is moved from the first location to the second location with inert gas in the liquid coolant system of the rack.

Example 14: The method of example 13, further including checking a pressure of the inert gas in the liquid coolant system of the rack before filling the rack with the liquid coolant at the second location.

Example 15: The method of example 13 or 14, further including purging the inert gas in the liquid coolant system of the rack before filling the rack with the liquid coolant at the second location.

Example 16: The method of any of examples 10-15, further including filling, at the second location, the liquid coolant from the separate storage container into the liquid coolant system of the rack.

Example 17: The method of example 16, wherein: the shipping crate is provided with a storage container subsystem and a pump subsystem, the storage container subsystem has the separate storage container containing the liquid coolant, a storage container inlet connector and a storage container outlet connector, the pump subsystem has a pump, a pump inlet connector, and a pump outlet connector, and filling the liquid coolant system of the rack includes: connecting the storage container outlet connector to the pump inlet connector; connecting the pump outlet connector to a supply side connector of the liquid coolant system of the rack; connecting the storage container inlet connector to a return side connector of the liquid coolant system of the rack; and causing the pump to move the liquid coolant from the separate storage container to the liquid coolant system.

Example 18: The method of example 16 or 17, further including draining the liquid coolant from the liquid coolant system of the rack at the second location.

Example 19: The method of example 18, wherein: the shipping crate is provided with a drain container subsystem comprising a drain container having a drain connector, and draining the liquid coolant from the liquid coolant system of the rack includes: connecting the drain connector to a return side connector of the liquid coolant system of the rack; connecting a supply side connector of the liquid coolant system of the rack to at least one of a compressed air cylinder or a vent; and filling the drain container with the liquid coolant from the liquid coolant system of the rack.

Example 20: The method according to example 19, further including moving the liquid coolant from the drain container to the storage container using a pump.

Example 21: A shipping crate, comprising: a storage tank subsystem having a storage tank arranged to contain liquid coolant, wherein the storage tank subsystem is positioned inside of the shipping crate, integrated into the shipping crate, or fixed to the shipping crate; and a pump subsystem having a pump arranged to pump the liquid coolant from the storage tank subsystem to a rack that houses electronic components cooled via a liquid coolant system of the rack when the rack is deployed and operating, wherein the pump subsystem is positioned inside of the shipping crate, integrated into the shipping crate, or fixed to the shipping crate.

Example 22: The shipping crate according to example 21, wherein the pump subsystem and the storage tank subsystem are integrated together.

Example 23: The shipping crate according to example 21 or 22, further comprising: at least one power source arranged to provide operational power to the pump subsystem.

Example 24: The shipping crate according to any of examples 21-23, further comprising: at least one elevation structure arranged to facilitate movement of the shipping crate via a forklift or a pallet jack.

### Conclusion

The terminology used herein is for the purpose of describing particular implementations only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, components, subsystems and/or groups but do not preclude the presence or addition of one or more other features, integers, steps, operations, elements, components, subsystems, and/or groups thereof. Further, the terms up, upper, down, lower, above, below, left, right, forward, rearward, first, second, third, and the like are intended to be understood in the context of the representations described and illustrated above so that a system, device, product, subsystem, and/or component may have such an orientation in reference to the frame or to various elements as supported by the frame or as illustrated in the drawing or figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various implementations were chosen and described in order to explain the principles of this disclosure and the practical application, and to enable others of ordinary skill in the art to understand this disclosure for various implementations with various modifications as are suited to the particular use contemplated.

What is claimed is:

1. A system to handle liquid coolant, the liquid coolant arranged for use in a liquid coolant system of a rack, the liquid coolant system having a coolant supply side and a coolant return side, the rack arranged to hold a plurality of electronic components, the system to handle liquid coolant comprising:
a storage tank subsystem having a storage tank to contain liquid coolant, a storage tank inlet, and a storage tank outlet;
a pump subsystem having a pump to pump the liquid coolant, a pump inlet, and a pump outlet, wherein the storage tank outlet is connectable with the pump inlet, the coolant supply side is connectable with the pump outlet, and the coolant return side is connectable to the storage tank inlet; and
a shipping crate, wherein the storage tank subsystem and the pump subsystem are at least one of positioned inside of the shipping crate, integrated into the shipping crate, or fixed to the shipping crate.

2. The system to handle liquid coolant according to claim 1, wherein the shipping crate is reuseable to re-ship the rack or to ship another rack arranged to hold a different set of electronic components.

3. The system to handle liquid coolant according to claim 1, further comprising:
a shut-off valve in the storage tank subsystem or the pump subsystem to resist flow of the liquid coolant.

4. The system to handle liquid coolant according to claim 1, wherein:
the storage tank subsystem further includes a storage tank inlet connector in communication with the storage tank inlet and a storage tank outlet connector in communication with the storage tank outlet,
the pump subsystem further includes a pump inlet connector in communication with the pump inlet and a pump outlet connector in communication with the pump outlet,
the liquid coolant system further includes a supply side coolant connector in communication with the coolant supply side and a return side coolant connector in communication with the coolant return side, and
the storage tank outlet connector is connectable with the pump inlet connector, the supply side coolant connector is connectable with the pump outlet connector, and the return side coolant connector is connectable with the storage tank inlet connector.

5. The system to handle liquid coolant according to claim 1, further comprising:
a drain tank subsystem having a drain tank inlet in communication with a drain tank, wherein the coolant return side is connectable to the drain tank subsystem.

6. The system to handle liquid coolant according to claim 5, wherein the drain tank and the storage tank are integrated into a single housing.

7. The system to handle liquid coolant according to claim 5, wherein at least one of the storage tank and the drain tank has a baffle configured to decrease movement of the liquid coolant during transport.

8. A method of handling a rack having a plurality of electronic components, the rack having a liquid coolant system, the method comprising:
providing the rack with the liquid coolant system in a shipping crate, wherein the liquid coolant system of the rack does not contain a liquid coolant;
providing the liquid coolant for the liquid coolant system in a separate storage container, the separate storage container being at least one of positioned inside of the shipping crate, integrated into the shipping crate, or fixed to the shipping crate; and
moving the shipping crate from a first location to a second location while the shipping crate contains the liquid coolant in the separate storage container.

9. The method according to claim 8, further comprising:
providing both the separate storage container containing the liquid coolant and the rack with the liquid coolant system not containing the liquid coolant in a same transit container; and
moving the same transit container from a first geographic address to a second geographic address.

10. The method according to claim 8, wherein the rack is moved from the first location to the second location with inert gas in the liquid coolant system of the rack.

11. The method according to claim 10, further comprising:
checking a pressure of the inert gas in the liquid coolant system of the rack before filling the rack with the liquid coolant after the shipping crate is moved.

12. The method according to claim 10, further comprising:
purging the inert gas in the liquid coolant system of the rack before filling the rack with the liquid coolant after the shipping crate is moved.

13. The method according to claim 8, further comprising:
after the shipping crate is moved, filling the liquid coolant from the separate storage container into the liquid coolant system of the rack.

14. The method according to claim 13, wherein:
the shipping crate is provided with a storage container subsystem and a pump subsystem,
the storage container subsystem has the separate storage container containing the liquid coolant, a storage container inlet connector and a storage container outlet connector,
the pump subsystem has a pump, a pump inlet connector, and a pump outlet connector, and
filling the liquid coolant system of the rack includes:
connecting the storage container outlet connector to the pump inlet connector;
connecting the pump outlet connector to a supply side connector of the liquid coolant system of the rack;
connecting the storage container inlet connector to a return side connector of the liquid coolant system of the rack; and
causing the pump to move the liquid coolant from the separate storage container to the liquid coolant system.

15. The method according to claim 13, further comprising:
draining the liquid coolant from the liquid coolant system of the rack.

16. The method according to claim 15, further comprising:
draining the liquid coolant from the liquid coolant system to the storage container using at least one pump.

17. A shipping crate, comprising:
a storage tank subsystem having a storage tank arranged to contain liquid coolant, wherein the storage tank subsystem is positioned inside of the shipping crate, integrated into the shipping crate, or fixed to the shipping crate; and
a pump subsystem having a pump arranged to pump the liquid coolant from the storage tank subsystem to a rack that houses electronic components cooled via a liquid coolant system of the rack when the rack is deployed and operating, wherein the pump subsystem is positioned inside of the shipping crate, integrated into the shipping crate, or fixed to the shipping crate.

18. The shipping crate according to claim 17, wherein the pump subsystem and the storage tank subsystem are integrated together.

19. The shipping crate according to claim 17, further comprising:
at least one power source arranged to provide operational power to the pump subsystem.

20. The shipping crate according to claim 17, further comprising:
at least one elevation structure arranged to facilitate movement of the shipping crate via a forklift or a pallet jack.
